(19) United States
(12) Patent Application Publication
(10) Pub. No.: US 2012/0183905 A1
(43) Pub. Date: Jul. 19, 2012

(54) CHARGED-PARTICLE BEAM DRAWING APPARATUS AND ARTICLE MANUFACTURING METHOD

(75) Inventors: Shigeru TERASHIMA, Utsunomiya-shi (JP); Takahiro NAKAYAMA, Utsunomiya-shi (JP)

(73) Assignee: CANON KABUSHIKI KAISHA, Tokyo (JP)

(21) Appl. No.: 13/347,981

(22) Filed: Jan. 11, 2012

(30) Foreign Application Priority Data
Jan. 19, 2011 (JP) 2011-009199

(51) Int. Cl. G03F 7/20; H01J 3/26

(52) U.S. Cl. 430/296; 250/396 R

(57) ABSTRACT

A drawing apparatus for drawing a pattern on a substrate by using a charged-particle beam comprises: a blanking deflector which deflects the charged-particle beam; a stopping aperture member which can block the charged-particle beam deflected by the blanking deflector; a catalyst which generates, from a gas, an active species for decomposing a deposit formed on the stopping aperture member; and a supply mechanism which supplies the gas to the catalyst. In a removing operation of removing the deposit, while the supply mechanism supplies the gas to the catalyst, the charged-particle beam irradiates a region which is not irradiated with the charged-particle beam in a drawing operation of drawing the pattern, thereby generating the active species from the gas by the catalyst positioned in at least the region, and removing the deposit by decomposing the deposit by the generated active species.

### BACKGROUND OF THE INVENTION

1. Field of the Invention

The present invention relates to a charged-particle beam drawing apparatus and article manufacturing method.

2. Description of the Related Art

A drawing apparatus using a plurality of charged-particle beams has already been proposed. Since charged particles are absorbed by gas components existing in the atmosphere and significantly decay, the interior of the drawing apparatus is held in a vacuum to such an extent that charged particles dot not decay. In this vacuum ambient in the drawing apparatus, gases mainly containing carbon compounds and water remain albeit slightly. These residual gases are generated from parts, cables, organic material components, and the like used in the drawing apparatus. Also, when charged-particle beams irradiate a photosensitive agent (resist) applied on a wafer as a drawing target, the molecular state of the resist changes, and volatile components are generated.

The above-mentioned residual gases repeat absorption and desorption on the surfaces of members used in the drawing apparatus, but they cause only physical absorption and do not cause adhesion or reaction on the member surfaces. In a portion such as a stopping aperture member that is irradiated with the charged-particle beams, however, the physically adsorbed gases are dissociated mainly due to secondary electrons generated in the irradiated portion. Substances generated from the dissociated gases sometimes are deposited on the member surfaces, or the generated reaction active species sometimes modify the member surfaces. These phenomena are called contaminations.

The following two phenomena are main contaminations among others. One is a phenomenon in which a carbon-containing component of the residual gases is physically adsorbed on the surface of a member forming a charged-particle beam drawing apparatus, and dissociated when the member is irradiated with a charged-particle beam, and a substance containing carbon is deposited on the member surface. The other is a phenomenon in which a water component adsorbed on the surface of a member of a charged-particle beam drawing apparatus is similarly dissociated when the member is irradiated with a charged-particle beam, and generated active oxygen oxidizes the member surface.

If a carbon-containing substance exceeding a given amount is deposited on the surface of a member of a charged-particle beam drawing apparatus or the member surface is oxidized, the electrical characteristics of the deposition portion or oxidized portion change. If carbon adhesion or surface oxidation occurs on the surface of a portion of a member as a conductor, the conductivity of the portion decreases. If this portion is further irradiated with a charged-particle beam, the electric charge of charged particles has no place to go and accumulates in the portion, so the portion gains a potential. This partial potential generation forms an electric field not originally set in the path of the charged-particle beam, and exerts considerable influence on the orbit of the charged-particle beam. As the degree of integration of semiconductor elements increases, the drawing position accuracy is required to be about a few nm or less. Therefore, the electric field caused by this charge accumulation cannot be neglected any longer.

Attempts have been made to avoid surface oxidation among these contaminations by forming members of a charged-particle beam drawing apparatus by using an oxidation-resistant material. On the other hand, the deposition of carbon or the like is regarded as unavoidable although there is a difference between the degrees of deposition, so attempts have been made to remove deposited carbon substances. Japanese Patent Laid-Open No. 2009-049438 has disclosed a method of supplying hydrogen gas near a member of a lithography apparatus on which a carbon substance is deposited, generating hydrogen radicals from the hydrogen gas by using a radical formation device, and removing the deposited carbon substance by using the generated hydrogen radicals. Japanese Patent Laid-Open No. 2009-049438 has also disclosed that the radical formation device for forming hydrogen radicals is at least one of a hot filament, plasma, radiation, and a catalyst. Japanese Patent No. 3047293 has disclosed a method by which internal structures of a charged-particle beam drawing apparatus are made of substances having a photocatalytic action, or the surfaces of the structures are coated with substances having a photocatalytic action, and the substances are irradiated with charged-particle beams, thereby decomposing contaminations adhered on the structures.

In a drawing apparatus that controls irradiation of a charged-particle beam by using a stopping aperture member for blocking a charged-particle beam deflected by a blanking deflector, a member that is presumably most influenced by the deposition of a carbon substance is the stopping aperture member. When blocking a charged-particle beam by using the stopping aperture member, the charged-particle beam is deflected by the blanking deflector, and a predetermined position on the surface of the stopping aperture member is irradiated with the charged-particle beam. As described previously, a carbon substance adheres and is deposited in this predetermined position due to the interaction between a carbon compound in the residual gas and charged particles or their secondary electrons. Since this position is further irradiated with the charged-particle beam, the surface of the carbon substance is electrified and generates a partial potential. This potential changes an electric field on the orbit of an unblocked charged-particle beam, i.e., a charged-particle beam necessary for drawing, and the orbit of the charged-particle beam slightly deviates from a set orbit, thereby shifting the arrival position of the charged-particle beam, i.e., the drawing position. This decreases the drawing accuracy, and deteriorates the performance of the apparatus.

Even when applying the conventional techniques of removing the deposited carbon substance as measures against the above-mentioned problem, other problems still remain. When a heating filament is set near the stopping aperture member in the technique described in Japanese Patent Laid-Open No. 2009-049438, the radiant heat of the heating filament raises the temperature of the stopping aperture member. Consequently, the stopping aperture member deforms due to thermal expansion, and the aperture position shifts. The deformed stopping aperture member hardly returns to the original state with high accuracy even when cooled later. In some cases, the aperture edge overlaps the orbit of a charged-particle beam. Also, when setting a member having a catalyst in the position of the heating filament in the technique described in Japanese Patent Laid-Open No. 2009-049438, the member having the catalyst obstructs the passing of a charged-particle beam. This interferes with a drawing operation by the charged-particle beam.

### SUMMARY OF THE INVENTION

The present invention provides a charged-particle beam drawing apparatus that efficiently removes a contaminant deposited on a stopping aperture member without obstructing a drawing operation by a charged-particle beam.

The present invention provides a drawing apparatus for drawing a pattern on a substrate by using a charged-particle beam, comprising: a blanking deflector which deflects the charged-particle beam; a stopping aperture member which can block the charged-particle beam deflected by the blanking deflector; a catalyst which generates, from a gas, an active species for decomposing a deposit formed on the stopping aperture member; and a supply mechanism which supplies the gas to the catalyst, wherein in a removing operation of removing the deposit, while the supply mechanism supplies the gas to the catalyst, the charged-particle beam irradiates a region which is not irradiated with the charged-particle beam in a drawing operation of drawing the pattern, thereby generating the active species from the gas by the catalyst positioned in at least the region, and removing the deposit by decomposing the deposit by the generated active species.

Further features of the present invention will become apparent from the following description of exemplary embodiments with reference to the attached drawings.

### BRIEF DESCRIPTION OF THE DRAWINGS

FIG. 1 is a schematic view showing the arrangement of an electron beam drawing apparatus according to the first embodiment;

FIG. 2 is a view showing the arrangement of a blanking deflector of the second embodiment;

FIG. 3 is a schematic view showing the arrangement of an electron beam drawing apparatus according to the third embodiment;

FIG. 4 is a schematic view showing the arrangement of an electron beam drawing apparatus according to the fourth embodiment; and

FIG. 5 is a view showing the arrangement of a blanking deflector of the fifth embodiment.

### DESCRIPTION OF THE EMBODIMENTS

The present invention is applicable to a drawing apparatus for drawing patterns on a substrate by using a plurality of charged-particle beams, and an example in which the present invention is applied to an electron beam drawing apparatus for drawing patterns on a substrate by using a plurality of electron beams will be explained below.

### First Embodiment

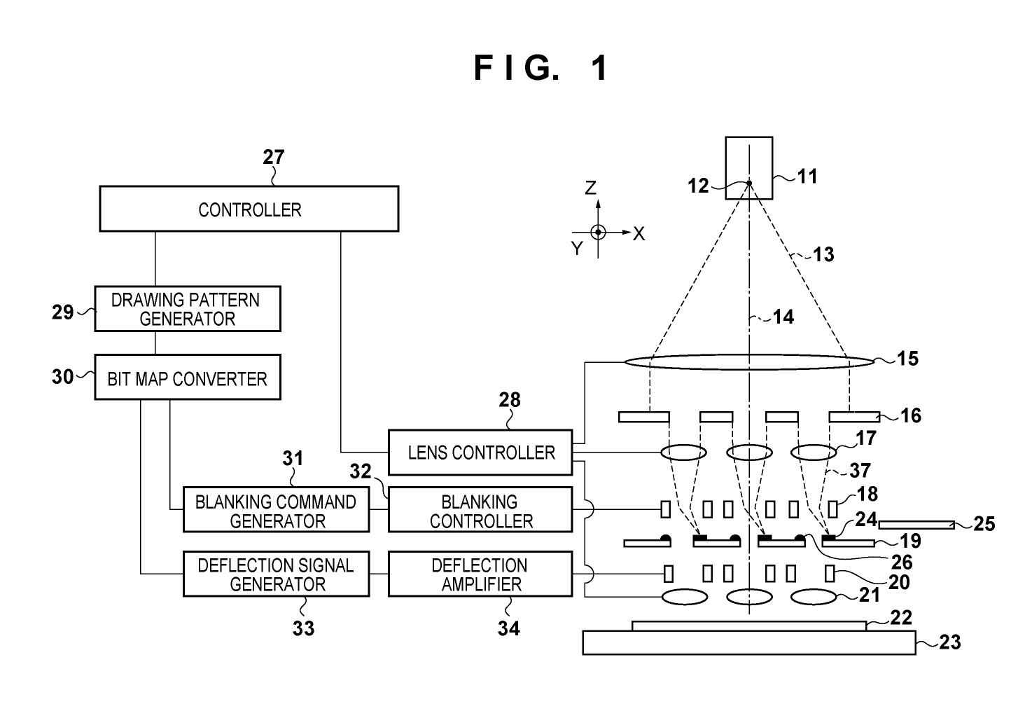

The arrangement of an electron beam drawing apparatus of the first embodiment will be explained below with reference to FIG. 1. An electron gun (charged-particle beam source) 11 forms a crossover 12. Reference numerals 13 and 14 denote the orbits of electrons emitted from the crossover 12. The electrons emitted from the crossover 12 form a parallel beam by the action of a collimator lens 15 formed by an electromagnetic lens, and the beam enters an aperture array 16. The aperture array 16 has a plurality of circular openings arranged in a matrix, and the incident electron beam is divided into a plurality of electron beams.

The electron beams having passed through the aperture array 16 enters a first electro-static lens 17 including three electrode plates (FIG. 1 shows the three plates as an integrated member) having circular openings. A stopping aperture member 19 having openings arranged in a matrix is set in a position where the first electro-static lens 17 first forms a crossover image. The stopping aperture member 19 can block electron beams deflected by a blanking deflector 18. The blanking deflector 18 obtained by arranging electrodes in a matrix executes an electron beam blanking operation by the stopping aperture member 19. A blanking controller 32 controls the blanking deflector 18, and a blanking signal generated by a drawing pattern generator 29, bit map converter 30, and blanking command generator 31 controls the blanking controller 32. A second electro-static lens 21 forms images of the electron beams that have passed through the stopping aperture member 19, thereby forming an image of the original crossover 12 on a substrate 22, such as a wafer or mask.

In a drawing operation of drawing a pattern, the substrate 22 is continuously moved in the X direction by a stage 23. Based on length measurement results obtained by the stage 23 as a laser length measuring device, an image on the surface of the substrate 22 is deflected in the Y direction by a deflector 20, and blanked by the blanking deflector 18. The deflector 20 is controlled by transmitting a deflection signal generated by a deflection signal generator 33 to a deflection amplifier 34. A lens controller 28 controls the collimator lens 15, first electro-static lens 17, and second electro-static lens 21. A controller 27 comprehensively controls the whole exposure operation. The controller 27, lens controller 28, drawing pattern generator 29, bit map converter 30, blanking command generator 31, blanking controller 32, and deflection signal generator 33 form a controller for controlling the electron beam drawing apparatus.

A drawing operation of this embodiment will be explained below. The electron beam 13 generated by the electron source 11 is divided into M rows×N columns by the aperture array 16, so as to form a staggered arrangement shifted from a lattice-like arrangement by a distance L in the X direction. When drawing a pattern, while the stage 23 continuously moves in the Y direction, the deflector 20 repetitively deflects the plurality of electron beams on the substrate surface for each pixel within the range of the distance L that can be scanned in the X direction. The deflection stroke of the deflector 20 determines the distance L. Also, the resist sensitivity and the value of the current density of the electron beam determine the stage velocity. After drawing is performed by continuously moving the substrate surface by the set distance in the Y direction, the stage 23 is moved by step-and-repeat in the Y direction, and continuous movement drawing is performed in the Y direction again. In a substrate returning position, step-and-repeat movement is performed in the X direction, and continuous movement drawing is performed in the Y direction again. Electron beam drawing is performed on the entire surface of the substrate 22 by repeating this operation.

When performing an electron beam blanking operation on the substrate 22 in the drawing operation explained above, the blanking deflector 18 deflects the electron beams to cause them to irradiate the stopping aperture member 19. In this case, as described previously, the residual gas of a carbon compound in the apparatus reacts with electrons on the surface of the stopping aperture member 19, and carbon contamination 26 is deposited on the surface. The conductivity of the carbon contamination 26 generated from the carbon compound is lower than that of a metal. When the portion where the carbon contamination 26 has been deposited is further irradiated with the electron beam, therefore, electrons hardly escape, and electric charge accumulates in the carbon contamination portion, thereby electrifying it. If a portion near the opening of the stopping aperture member 19 is electrified, distortion occurs in the electric field around the electrified portion, and this exerts influence on the orbit of the electron beams passing through the stopping aperture member 19. To prevent this, it is necessary to periodically remove the deposit of the carbon contamination 26. In this embodiment, a catalyst 24 is set in a portion of the surface of the stopping aperture member 19, which opposes the blanking deflector 18. By irradiating the catalyst placed near the carbon contamination 26 with the electron beam while supplying hydrogen gas (a gas), hydrogen radicals are generated from the hydrogen gas, and the carbon contamination 26 is decomposed and removed by the hydrogen radicals.

FIG. 1 shows the state of the electron beam drawing apparatus when generating hydrogen radicals in order to remove the carbon contamination 26. As shown in FIG. 1, a tungsten layer 24 as a catalyst is formed in a region of the surface of the stopping aperture member 19, which is opposite, with respect to an aperture hole, to a region to be irradiated with the electron beam in the drawing operation. While the drawing operation is performed using the electron beams, the carbon contamination 26 is deposited in the electron beam irradiated positions. When the carbon contamination 26 reaches a predetermined amount, for example, a thickness of about 50 nm, the drawing operation is temporarily stopped by stopping electron beam irradiation. Then, a removing operation of removing the carbon contamination 26 deposited on the stopping aperture member 19 is executed. First, hydrogen gas is supplied from a hydrogen gas inlet 25 as a gas supply mechanism such that the pressure is 10⁻² to 10 Pa (for example, about 1 Pa), and electron beam irradiation is resumed. In this state, a voltage opposite to that in the drawing operation is applied to the whole blanking deflector 18. More specifically, since one of the pair of electrodes is grounded, a voltage different from a voltage to be applied to the other, that is, a voltage having the opposite polarity is applied. For example, if a voltage of +5 V is applied in normal drawing, a voltage of −5 V is applied. Consequently, as shown in FIG. 1, electron beams 37 are deflected in the direction opposite to that in the drawing operation, and irradiate the tungsten layers 24 on the stopping aperture member 19.

Hydrogen adsorbed by dissociation on the surface of the tungsten layer 24 gains the energy of the electron beams and is desorbed in an atomic state from the surface. Hydrogen radicals (active species) in this atomic state are highly active. Therefore, the hydrogen radicals react with the carbon contamination 26 existing nearby, and are desorbed as hydrocarbon gas from the surface of the stopping aperture member 19. This reaction can remove the carbon contamination 26 from the stopping aperture member 19. As shown in FIG. 1, all the electron beams simultaneously irradiate the tungsten layers 24 in a plurality of portions. This makes it possible to generate hydrogen radicals in the entire portion near the carbon contamination 26, and efficiently remove the carbon contamination 26. When this removing operation is performed for a predetermined time, the carbon contamination 26 disappears or reduces. Consequently, the surface of the stopping aperture member 19 is not electrified any longer, so the drawing operation can be resumed. After that, electron beam irradiation is temporarily stopped again, the vacuum degree in the internal space of the apparatus is raised by stopping the supply of hydrogen gas, and then the drawing operation is resumed.

The removing operation as described above is performed when the deposition amount of the carbon contamination 26 increases. However, the removing operation may also be performed for every predetermined time because it is not easy to monitor the deposition amount of the carbon contamination 26 on the stopping aperture member 19. For example, the removing operation can be performed every day at predetermined time, and can also be performed for every few days. As the interval of the removing operation shortens, the deposition amount of the carbon contamination 26 reduces, so the time required for the removing operation shortens. Although tungsten is used as the catalyst in this embodiment, another material may also be used as long as the material has the same catalytic action. For example, it is possible to use platinum, palladium, molybdenum, nickel, ruthenium, and alloys and compounds of these elements as the catalyst. Also, a gas to be supplied to remove the carbon contamination 26 is not limited to hydrogen, and can also be nitrogen, fluorine, or oxygen. Furthermore, this embodiment uses a plurality of electron beams, but it is also possible to use a single electron beam.

In this embodiment, the catalyst is placed in the position of a portion on the stopping aperture member, which is not irradiated with any electron beam during the drawing operation, and, in the operation of removing the carbon contamination 26, the catalyst is irradiated with the electron beam by deflecting it. In this embodiment, the catalyst is not irradiated with any electron beam in the normal drawing operation. In the normal drawing operation, therefore, no carbon contamination 26 adheres to the catalyst, so the function of the catalyst does not deteriorate. Accordingly, the catalyst having the full function can efficiently generate active species when removing the carbon contamination 26.

### Second Embodiment

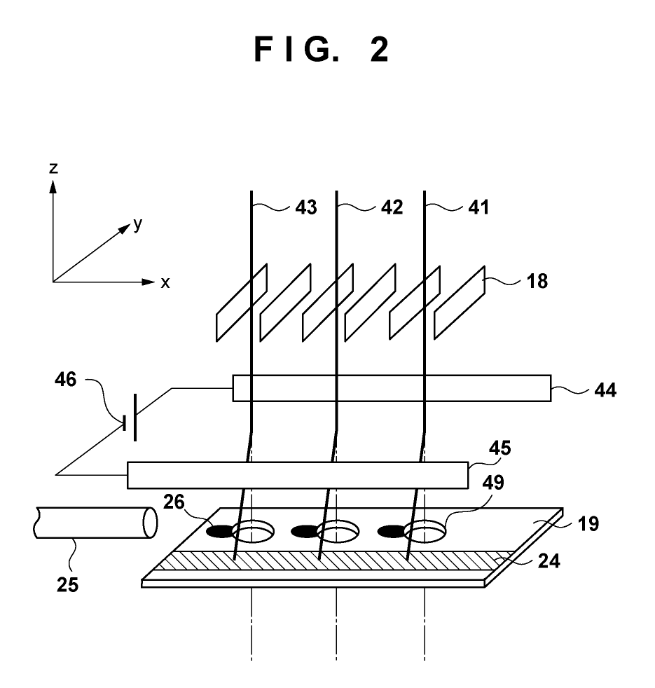

FIG. 2 three-dimensionally expresses a portion including a blanking deflector 18 and stopping aperture member 19 of an electron beam drawing apparatus according to the second embodiment. Referring to FIG. 2, each electron beam is simply represented by one thick line. When irradiating a catalyst with an electron beam in the first embodiment, the deflecting direction of an electron beam 41 is changed to the opposite direction by applying, to the blanking deflector 18, a voltage having polarity opposite to that in the normal drawing operation. In this case, it is necessary to prepare two types of power supplies in the system for applying a voltage to the blanking deflector 18, and cause all of a number of electrodes to perform a switching operation. This increases the load on a blanking controller 32.

In the second embodiment, therefore, the deflecting directions of electron beams are simultaneously controlled by using additionally installed deflecting electrodes 44 and 45 to be used only when removing carbon contamination 26. As shown in FIG. 2, the deflecting electrodes 44 and 45 form a deflector capable of deflecting electron beams in a direction different from the deflecting direction of the blanking deflector 18, for example, a direction perpendicular to the deflecting direction of the blanking deflector 18. In addition, the deflecting electrodes 44 and 45 are designed to apply an electric field to the paths of a number of electron beams, and hence can collectively deflect a number of electron beams.

As in the first embodiment, if the deposition amount of the carbon contamination 26 existing in the −X direction of each opening 49 of the stopping aperture member 19 exceeds a tolerance, a drawing operation is stopped, and a removing operation is started. In the operation of removing the carbon contamination 26, a voltage 46 is applied between the deflecting electrodes 44 and 45 while hydrogen gas is supplied from a hydrogen gas inlet 25, thereby simultaneously deflecting electron beams 41, 42, and 43 in the −Y direction. The deflecting direction is the −Y direction that makes an angle of 90° with the deflecting direction (−X direction) in the normal drawing operation. As shown in FIG. 2, a belt-like tungsten layer 24 is formed in a peripheral region in the −Y direction on the stopping aperture member 19, which is irradiated with the electron beams 41, 42, and 43 by this deflection.

When the removing operation is repeated many times, the tungsten layer 24 may oxidize, contamination may adhered on the tungsten layer 24, or the surface of the tungsten layer 24 may be roughened. In a case like this, a voltage used in the drawing operation is applied to the blanking deflector 18 at the same time a voltage is applied between the deflecting electrodes 44 and 45. Consequently, the electron beam irradiation position is deflected in the direction of, for example, 45° to the electron beam deflecting direction in the drawing operation. Since the tungsten layer 24 is formed into a belt-like shape, a region where the catalytic action of the tungsten layer 24 is high can be irradiated with the electron beams.

In the second embodiment, the deflecting electrodes 44 and 45 for deflecting the electron beams toward the surface of the catalyst are additionally installed between the blanking deflector 18 and the stopping aperture member 19. This gives the second embodiment the ability to eliminate the load on the blanking controller 32, and simultaneously deflect a number of electron beams toward the surface of the catalyst.

### Third Embodiment

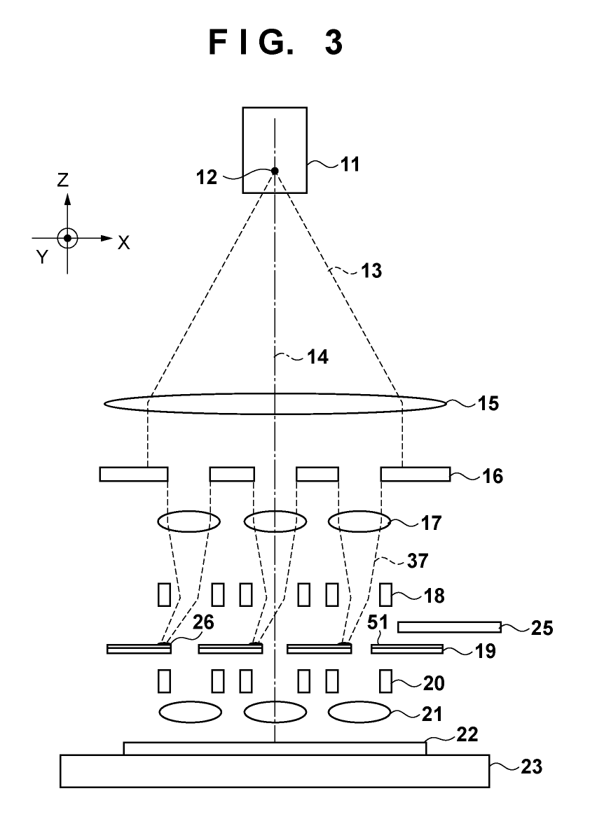

An electron beam drawing apparatus according to the third embodiment will be explained below with reference to FIG. 3. In the third embodiment, a platinum layer 51 as a catalyst is formed in a region that is irradiated with electron beams in a drawing operation, in addition to a region that is not irradiated with any electron beams in the drawing operation, on the surface of a stopping aperture member 19, which opposes a blanking deflector 18. For example, the platinum layer 51 is formed on the entire surface of the stopping aperture member 19. Platinum is a metal having a high conductivity and also has an oxidation resistance, and hence is suitable as a surface material of the stopping aperture member 19. Even when platinum is used as the surface of the stopping aperture member 19, however, it is not possible to prevent carbon contamination 26 from adhering to and being deposited on the surface.

In a normal drawing operation, the carbon contamination 26 adheres to the surface of the stopping aperture member 19. In the third embodiment, a removing operation is performed before the carbon contamination 26 is deposited by a large thickness (for example, about 10 nm or more). The deposition amount of the carbon contamination 26 is presumably about a few nm when the drawing operation is performed one day, although it also depends on the type and amount of carbon compound residual gas in the apparatus.

In this case, the carbon contamination 26 does not evenly thinly adhere to the entire surface of the stopping aperture member 19, but often adheres in the form of islands. In a state like this, electron beams 37 are emitted while hydrogen gas is supplied from a hydrogen gas inlet 25, so that the pressure is, for example, about 1 Pa. Consequently, the catalytic action of the partially exposed platinum layer 51 generates hydrogen radicals, and the hydrogen radicals can react with the carbon contamination 26 having adhered in the form of islands. This method loses its removing effect if the carbon contamination 26 is deposited to completely cover the entire surface of the platinum layer 51. Therefore, the removing operation must frequently be performed.

The merit of the third embodiment is the ability to remove the carbon contamination 26 without additionally installing any opposite voltage circuit as in the first embodiment, or any deflecting electrodes 44 and 45 for simultaneously deflecting a number of electron beams as in the second embodiment. Also, in the arrangement of the third embodiment, the blanking deflector 18 in the normal drawing operation is directly used, so a slight amount of hydrogen gas can be supplied during the drawing operation. For example, hydrogen gas is supplied near the stopping aperture member 19 such that the pressure is about 1×10⁻³ Pa.

A hydrogen gas ambient like this has almost no influence on electron beams. When the normal drawing operation is advanced in this state, electron beams irradiate the stopping aperture member 19 when blanked. On the surface of the stopping aperture member 19 irradiated with the electron beams, the carbon contamination 26 adheres to a portion where a carbon compound residual gas is adsorbed, and hydrogen radicals are generated in a portion where hydrogen is adsorbed. These hydrogen radicals suppress the deposition of the carbon contamination 26. Since the supply amount of hydrogen is small, however, the deposition of the carbon contamination 26 is difficult to eliminate. If the hydrogen supply amount is excessively increased when performing the drawing operation, adverse effects are exerted on the orbits of electron beams, and on the actions of first and second electro-static lenses 17 and 21.

### Fourth Embodiment

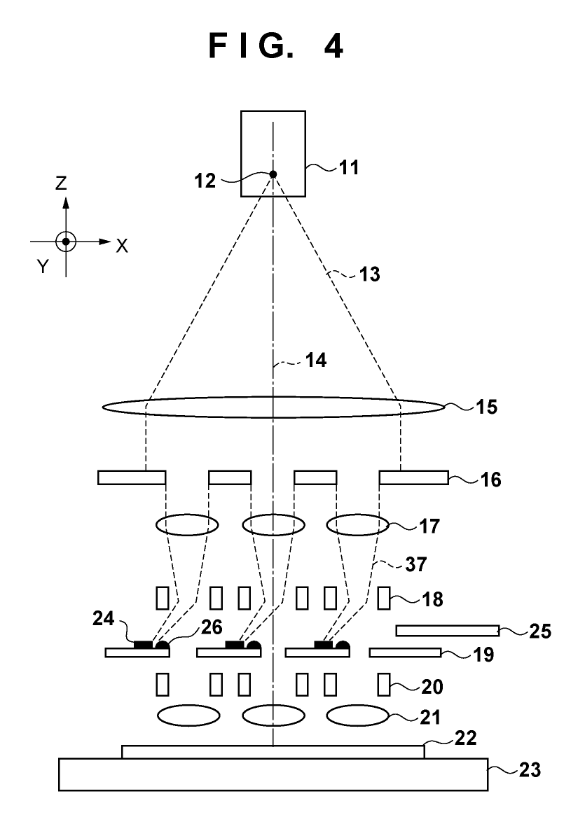

An electron beam drawing apparatus according to the fourth embodiment will be explained below with reference to FIG. 4. In the fourth embodiment, a tungsten layer 24 as a catalyst is formed in a position on a stopping aperture member 19, which is shifted in the −X direction from a position to be irradiated with electron beams 37 in a drawing operation. In the fourth embodiment, the accelerating voltage of an electron beam 13 is changed when removing carbon contamination 26. As a practical example, when performing a removing operation, the accelerating voltage is set to about half that of a normal drawing operation. In this state, a blanking deflector 18 deflects the electron beams 37, while hydrogen gas is supplied from a hydrogen gas inlet 25. During the process, the whole blanking deflector deflects the orbits of the electron beams.

Since the accelerating voltage for the electron beams is about half, the electron orbit deflection amount is about double. Accordingly, the electron beams irradiate a catalyst layer 52 on the stopping aperture member 19, beyond a portion to be irradiated with the electron beams in the drawing operation, that is, a portion where the carbon contamination 26 has been deposited. Consequently, hydrogen molecules are activated to generate hydrogen radicals on the surface of the tungsten layer 24, and this makes it possible to efficiently remove the carbon contamination 26. Note that the tungsten layer 24 may also be formed on the entire surface of the stopping aperture member 19 as in the third embodiment. The merit of the fourth embodiment is the ability to remove the carbon contamination 26 without additionally installing the opposite voltage circuit of the first embodiment, or the deflecting electrodes 44 and 45 for simultaneously deflecting a number of electron beams in the second embodiment, because the electron beam accelerating voltage is variable.

### Fifth Embodiment

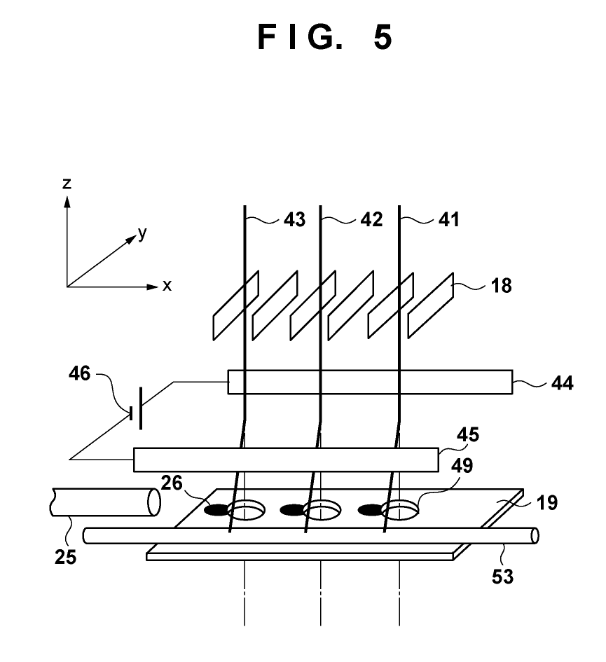

An electron beam drawing apparatus according to the fifth embodiment will be explained below with reference to FIG. 5. In the fifth embodiment, a catalyst is not formed as a layer on a stopping aperture member 19. In the space between a blanking deflector 18 and the stopping aperture member 19, a tungsten wire 53 extending in the X direction is placed in a position in the −Y direction, which is not irradiated with electron beams 41, 42, and 43 in a normal drawing operation. In this embodiment, deflecting electrodes 44 and 45 explained in the second embodiment are additionally installed in a direction (the X direction) parallel to the electron beam deflecting direction of the blanking deflector 18 in the normal drawing operation.

When removing carbon contamination 26, the deflecting electrodes 44 and 45 deflect the orbits of electron beams in the −Y direction while hydrogen gas is supplied from a hydrogen gas inlet 25, thereby irradiating the tungsten wire 53 with the electron beams 41, 42, and 43. Consequently, hydrogen molecules are activated to generate hydrogen radicals on the surface of the tungsten wire 53, and the carbon contamination 26 can be removed by the hydrogen radicals. During the process, a positive voltage of a few V may be applied to the tungsten wire 53. This allows the electron beams 41, 42, and 43 to intensively irradiate the tungsten wire 53.

The merit of the fifth embodiment is that a catalyst layer deposition step can be omitted in the manufacture of the stopping aperture member 19, because no catalyst layer is formed on the stopping aperture member 19. Also, in the fifth embodiment, even when the catalyst deteriorates because it is excessively irradiated with electron beams, maintenance is easy because the stopping aperture member 19 and catalyst are separated parts. Although the tungsten wire 53 is used as a catalyst in the fifth embodiment, it is also possible to use a mesh-like structure corresponding to the period of electron beams in the form of a matrix. Furthermore, the catalyst is not limited to tungsten.

### Article Manufacturing Method

An article manufacturing method according to an embodiment of the present invention is suitable for the manufacture of an article, for example, a microdevice such as a semiconductor device or an element having a microstructure. This manufacturing method can include a step of forming a latent image pattern on a photosensitive agent applied on a substrate (a step of performing drawing on the substrate), by using the above-mentioned drawing apparatus, and a step of developing the substrate on which the latent image pattern is formed in the former step. The manufacturing method can further include other well-known steps (for example, oxidation, deposition, vapor deposition, doping, planarization, etching, resist removal, dicing, bonding, and packaging). When compared to conventional methods, the article manufacturing method of this embodiment is advantageous in at least one of the performance, quality, productivity, and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-009199 filed Jan. 19, 2011, which is hereby incorporated by reference herein in its entirety.

What is claimed is:

1. A drawing apparatus for drawing a pattern on a substrate by using a charged-particle beam, comprising:
a blanking deflector which deflects the charged-particle beam;
a stopping aperture member which can block the charged-particle beam deflected by said blanking deflector;
a catalyst which generates, from a gas, an active species for decomposing a deposit formed on said stopping aperture member; and
a supply mechanism which supplies the gas to said catalyst,
wherein in a removing operation of removing the deposit, while said supply mechanism supplies the gas to said catalyst, the charged-particle beam irradiates a region which is not irradiated with the charged-particle beam in a drawing operation of drawing the pattern, thereby generating the active species from the gas by said catalyst positioned in at least the region, and removing the deposit by decomposing the deposit by the generated active species.

2. The apparatus according to claim 1, wherein said catalyst is positioned in a portion of a surface of said stopping aperture member, which opposes said blanking deflector.

3. The apparatus according to claim 1, wherein said catalyst is positioned between said stopping aperture member and said blanking deflector.

4. The apparatus according to claim 1, wherein during the removing operation, the region is irradiated with the charged-particle beam by applying, to said blanking deflector, a voltage different from a voltage applied during the drawing operation.

5. The apparatus according to claim 4, wherein during the removing operation, a voltage having polarity opposite to that of a voltage to be applied to said blanking deflector during the drawing operation is applied to said blanking deflector.

6. The apparatus according to claim 1, wherein during the removing operation, the region is irradiated with the charged-particle beam by applying an accelerating voltage different from that applied during the drawing operation, to a charged-particle beam source for generating the charged-particle beam.

7. The apparatus according to claim 1, further comprising a deflector which deflects the charged-particle beam in a direction different from a direction in which the charged-particle beam is deflected by said blanking deflector,
wherein during the removing operation, the region is irradiated with the charged-particle beam by deflecting the charged-particle beam by said deflector.

8. The apparatus according to claim 7, wherein during the removing operation, the region is irradiated with the charged-particle beam by deflecting the charged-particle beam by said deflector and said blanking deflector.

9. The apparatus according to claim 1, wherein said catalyst is positioned in a region which is irradiated with the charged-particle beam in the drawing operation, in addition to a region which is not irradiated with the charged-particle beam in the drawing operation, on the surface of said stopping aperture member, which opposes said blanking deflector.

10. The apparatus according to claim 9, wherein said catalyst is platinum.

11. The apparatus according to claim 1, wherein the gas is hydrogen.

12. A method of manufacturing an article, the method comprising:
drawing a pattern on a substrate by using a drawing apparatus for performing drawing on a substrate by using a charged-particle beam;
developing the substrate on which the pattern is drawn; and
processing the developed substrate,
wherein the drawing apparatus comprises:
a blanking deflector which deflects the charged-particle beam;
a stopping aperture member which can block the charged-particle beam deflected by the blanking deflector;
a catalyst which generates, from a gas, an active species for decomposing a deposit formed on the stopping aperture member; and
a supply mechanism which supplies the gas to the catalyst,
wherein in a removing operation of removing the deposit,
while the supply mechanism supplies the gas to the catalyst, the charged-particle beam irradiates a region which is not irradiated with the charged-particle beam in a drawing operation of drawing the pattern, thereby
generating the active species from the gas by the
catalyst positioned in at least the region, and removing the deposit by decomposing the deposit by the
generated active species.
